(19) United States
(12) Patent Application Publication
(10) Pub. No.: US 2026/0180519 A1
(43) Pub. Date: Jun. 25, 2026

(54) DYNAMIC AMPLIFIER THAT AMPLIFIES MULTIPLE INPUTS SIMULTANEOUSLY

(71) Applicant: REALTEK SEMICONDUCTOR CORPORATION, HSINCHU (TW)

(72) Inventor: SHIH-HSIUNG HUANG, HSINCHU (TW)

(21) Appl. No.: 19/426,472

(22) Filed: Dec. 19, 2025

(30) Foreign Application Priority Data
Dec. 23, 2024 (TW) 113150244

(51) Int. Cl. H03F 3/00; H03F 1/02; H03F 1/26

(52) U.S. Cl. CPC H03F 3/005; H03F 1/0216; H03F 1/26

(57) ABSTRACT

A dynamic amplifier includes first to sixth transistors and a power supply circuit. The first transistor is configured to amplify a first input signal. The second transistor amplifies a second input signal. The third transistor amplifies a third input signal, in which the first to the third transistors collectively generate a first output signal at a first output node in response to the first to third input signals. The fourth transistor amplifies a fourth input signal. The fifth transistor amplifies a fifth input signal. The sixth transistor amplifies a sixth input signal, in which the fourth to the sixth transistors collectively generate a second output signal at a second output node in response to the fourth to sixth input signals. The power supply circuit dynamically provides power voltages to drive the first to the sixth transistors.

### BACKGROUND OF THE INVENTION

### 1. Field of the Invention

The present disclosure relates to an amplifier, and more particularly, to a dynamic amplifier configured to generate a superposition output of amplified signals without using additional circuit(s).

### 2. Description of Related Art

In some applications, there may be a need to amplify multiple input signals (or multiple sets of differential signals) and combine the amplified signals. For example, inputs of an integrator in a delta-sigma modulator may be three or more input signals (or three or more sets of differential signals). An existing circuit solution is to employ multiple independent amplifiers to respectively amplify the input signals, and to combine the outputs of the amplifiers through a combination circuit. However, the combination circuit in existing solution may employ components such as switches and capacitors, causing the signals to be attenuated due to issues such as charge sharing during combination, and may also introduce unnecessary noise due to these components, thereby reducing the signal accuracy and operating speed.

### SUMMARY OF THE INVENTION

In some aspects, an object of the present disclosure is to, but not limited to, provide a dynamic amplifier configured to generate a superposition output of amplified signals without using additional circuit(s), so as to make an improvement to the prior art.

In some aspects, a dynamic amplifier includes a first transistor, a second transistor, a third transistor, a fourth transistor, a fifth transistor, a sixth transistor, and a power supply circuit. The first transistor is configured to amplify a first input signal. The second transistor is configured to amplify a second input signal. The third transistor is configured to amplify a third input signal, in which the first transistor, the second transistor, and the third transistor are configured to collectively generate a first output signal at a first output node in response to the first input signal, the second input signal, and the third input signal. The fourth transistor is configured to amplify a fourth input signal. The fifth transistor is configured to amplify a fifth input signal. The sixth transistor is configured to amplify a sixth input signal, in which the fourth transistor, the fifth transistor, and the sixth transistor are configured to collectively generate a second output signal at a second output node in response to the fourth input signal, the fifth input signal, and the sixth input signal. The power supply circuit is configured to dynamically provide a plurality of power voltages to drive the first transistor, the second transistor, the third transistor, the fourth transistor, the fifth transistor, and the sixth transistor.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of a dynamic amplifier according to some embodiments of the present disclosure.

FIG. 2 illustrates a schematic diagram of a dynamic amplifier according to some embodiments of the present disclosure.

FIG. 3 illustrates a schematic diagram of a dynamic amplifier according to some embodiments of the present disclosure.

FIG. 4 illustrates a schematic diagram of a dynamic amplifier according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuit” may indicate an object, which is formed with one or more transistors and/or one or more active/passive elements according to a specific arrangement, for processing signals.

As used herein, the term “and/or” includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

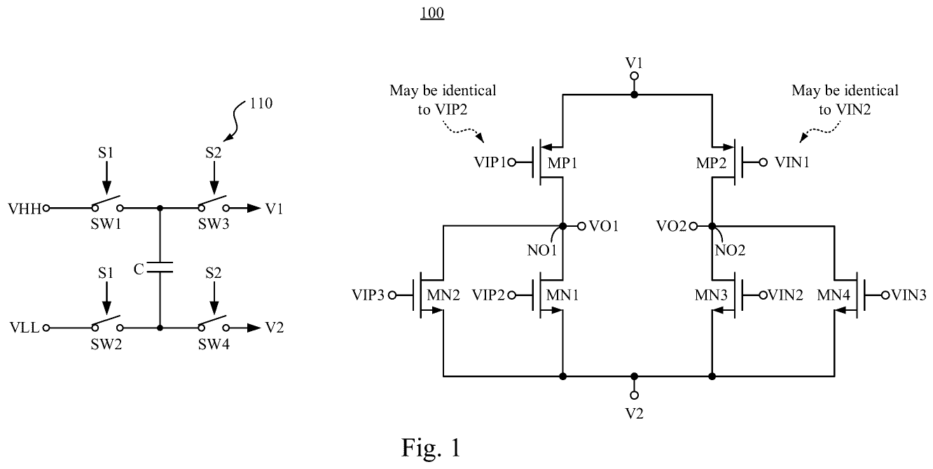

FIG. 1 illustrates a schematic diagram of a dynamic amplifier 100 according to some embodiments of the present disclosure. The dynamic amplifier 100 includes a power supply circuit 110, a transistor MP1, a transistor MP2, a transistor MN1, a transistor MN2, a transistor MN3, and a transistor MN4.

The power supply circuit 110 is configured to dynamically provide a power voltage V1 and a power voltage V2 to drive the transistor MP1, the transistor MP2, the transistor MN1, the transistor MN2, the transistor MN3, and the transistor MN4. In some embodiments, the power supply circuit 110 may include a switch SW1, a switch SW2, a capacitor C, a switch SW3, and a switch SW4. A first terminal of the switch SW1 receives a supply voltage VHH, a second terminal of the switch SW1 is coupled to a first terminal of the capacitor C, and a control terminal of the switch SW1 receives a switching signal S1. A first terminal of the switch SW2 receives a supply voltage VLL, a second terminal of the switch SW2 is coupled to a second terminal of the capacitor C, and a control terminal of the switch SW2 receives the switching signal S1. A first terminal of the switch SW3 is coupled to the first terminal of the capacitor C, a second terminal of the switch SW3 outputs the power voltage V1, and a control terminal of the switch SW3 receives a switching signal S2. A first terminal of the switch SW4 is coupled to the second terminal of the capacitor C, a second terminal of the switch SW4 outputs the power voltage V2, and a control terminal of the switch SW4 receives the switching signal S2. With the above arrangement, the switch SW1 and the switch SW2 may be turned on according to the switching signal S1 to respectively provide the supply voltage VHH and the supply voltage VLL to the capacitor C, so that the capacitor C may be charged by the supply voltage VHH and the supply voltage VLL. The switch SW3 and the switch SW4 may be turned on according to the switching signal S2 to respectively output the voltage at the first terminal of the capacitor C as the power voltage V1 and the voltage at the second terminal of the capacitor C as the power voltage V2. In other words, when the switch SW1 and the switch SW2 are turned on, the switch SW3 and the switch SW4 are not turned on, and the capacitor C may be charged by the supply voltage VHH and the supply voltage VLL. When the switch SW3 and the switch SW4 are turned on, the switch SW1 and the switch SW2 are not turned on, so that the switch SW3 and the switch SW4 may provide the power voltage V1 and the power voltage V2 accordingly.

A first terminal (e.g., a source) of the transistor MP1 receives the power voltage V1, a second terminal (e.g., a drain) of the transistor MP1 is coupled to an output node NO1, and a control terminal (e.g., a gate) of the transistor MP1 receives an input signal VIP1. A first terminal (e.g., a drain) of the transistor MN1 is coupled to the output node NO1, a second terminal (e.g., a source) of the transistor MN1 receives the power voltage V2, and a control terminal (e.g., a gate) of the transistor MN1 receives an input signal VIP2. A first terminal of the transistor MN2 is coupled to the output node NO1, a second terminal of the transistor MN2 receives the power voltage V2, and a control terminal of the transistor MN2 receives an input signal VIP3. With the above arrangement, the transistor MP1 and the transistor MN1 may be coupled in series through the output node NO1, and the transistor MN2 may be coupled in parallel to the transistor MN1. The transistor MP1 is configured to amplify the input signal VIP1, the transistor MN1 is configured to amplify the input signal VIP2, and the transistor MN2 is configured to amplify the input signal VIP3, and collectively generate an output signal VO1 at the output node NO1. In other words, in response to the input signal VIP1, the input signal VIP2, and the input signal VIP3, the transistor MP1, the transistor MN1, and the transistor MN2 are configured to collectively generate the output signal VO1 at the output node NO1, in which the output signal VO1 may be a signal formed by combining a signal obtained by amplifying the input signal VIP1 through the transistor MP1, a signal obtained by amplifying the input signal VIP2 through the transistor MN1, and a signal obtained by amplifying the input signal VIP3 through the transistor MN2.

A first terminal of the transistor MP2 receives the power voltage V1, a second terminal of the transistor MP2 is coupled to an output node NO2, and a control terminal of the transistor MP2 receives an input signal VIN1. A first terminal of the transistor MN3 is coupled to the output node NO2, a second terminal of the transistor MN3 receives the power voltage V2, and a control terminal of the transistor MN3 receives an input signal VIN2. A first terminal of the transistor MN4 is coupled to the output node NO2, a second terminal of the transistor MN4 receives the power voltage V2, and a control terminal of the transistor MN4 receives an input signal VIN3. With the above arrangement, the transistor MP2 and the transistor MN3 may be coupled in series through the output node NO2, and the transistor MN4 may be coupled in parallel to the transistor MN3. The transistor MP2 is configured to amplify the input signal VIN1, the transistor MN3 is configured to amplify the input signal VIN2, and the transistor MN4 is configured to amplify the input signal VIN3, and collectively generate an output signal VO2 at the output node NO2. In other words, in response to the input signal VIN1, the input signal VIN2, and the input signal VIN3, the transistor MP2, the transistor MN3, and the transistor MN4 are configured to collectively generate the output signal VO2 at the output node NO2, in which the output signal VO2 may be a signal formed by combining a signal obtained by amplifying the input signal VIN1 through the transistor MP2, a signal obtained by amplifying the input signal VIN2 through the transistor MN3, and a signal obtained by amplifying the input signal VIN3 through the transistor MN4.

In some embodiments, the input signal VIP1 may be identical to the input signal VIP2, so that the transistor MP1 and the transistor MN1 are configured to amplify the same input signal VIP2. Similarly, in some embodiments, the input signal VIN1 may be identical to the input signal VIN2, so that the transistor MP2 and the transistor MN3 are configured to amplify the same input signal VIN2. In some embodiments, the input signal VIP2 and the input signal VIN2 may be a set of differential signals, and the input signal VIP3 and the input signal VIN3 may be another set of differential signals.

With the above configuration, the dynamic amplifier 100 may simultaneously amplify multiple input signals (or multiple sets of differential signals) and may generate a superposition (i.e., the output signal VO1 and the output signal VO2) of the amplified input signals (or the amplified sets of differential signals) without using additional circuit(s). As a result, it is able to avoid attenuation of the output signal VO1 and the output signal VO2 caused by additional circuit(s).

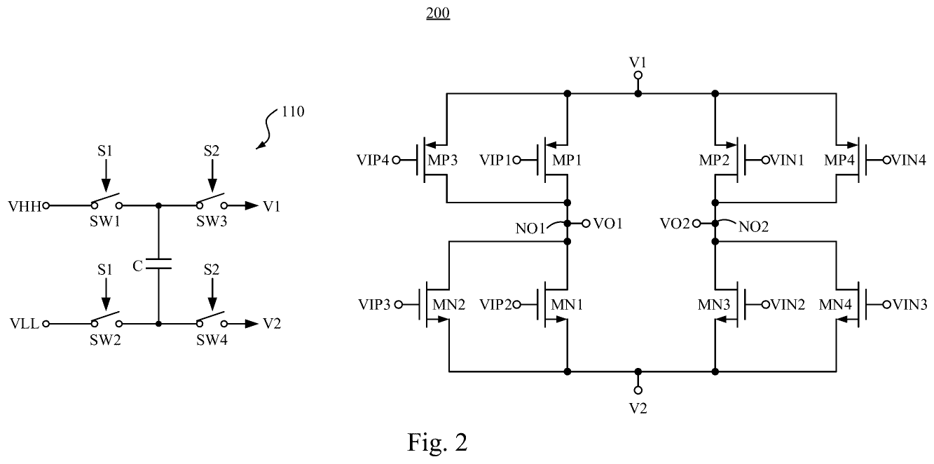

FIG. 2 illustrates a schematic diagram of a dynamic amplifier 200 according to some embodiments of the present disclosure. Compared with FIG. 1, the dynamic amplifier 200 further includes a transistor MP3 and a transistor MP4. A first terminal of the transistor MP3 receives the power voltage V1, a second terminal of the transistor MP3 is coupled to the output node NO1, and a control terminal of the transistor MP3 receives an input signal VIP4. With the above arrangement, the transistor MP3 and the transistor MN2 may be coupled in series through the output node NO1, and the transistor MP3 may be coupled in parallel to the transistor MP1. The transistor MP3 is configured to amplify the input signal VIP4, and the transistor MP3, the transistor MP1, the transistor MN1, and the transistor MN2 are configured to collectively generate the output signal VO1 at the output node NO1.

Similarly, a first terminal of the transistor MP4 receives the power voltage V1, a second terminal of the transistor MP4 is coupled to the output node NO2, and a control terminal of the transistor MP4 receives an input signal VIN4. With the above arrangement, the transistor MP4 and the transistor MN4 may be coupled in series through the output node NO2, and the transistor MP4 may be coupled in parallel to the transistor MP2. The transistor MP4 is configured to amplify the input signal VIN4, and the transistor MP4, the transistor MP2, the transistor MN3, and the transistor MN4 are configured to collectively generate the output signal VO2 at the output node NO2.

In some embodiments, the input signal VIP1 and the input signal VIN1 may be a first set of differential signals, the input signal VIP2 and the input signal VIN2 may be a second set of differential signals, the input signal VIP3 and the input signal VIN3 may be a third set of differential signals, and the input signal VIP4 and the input signal VIN4 may be a fourth set of differential signals. Under such conditions, the dynamic amplifier 200 may simultaneously process four sets of differential signals and generate a superposition output of amplified four sets of differential signals as the output signal VO1 and the output signal VO2.

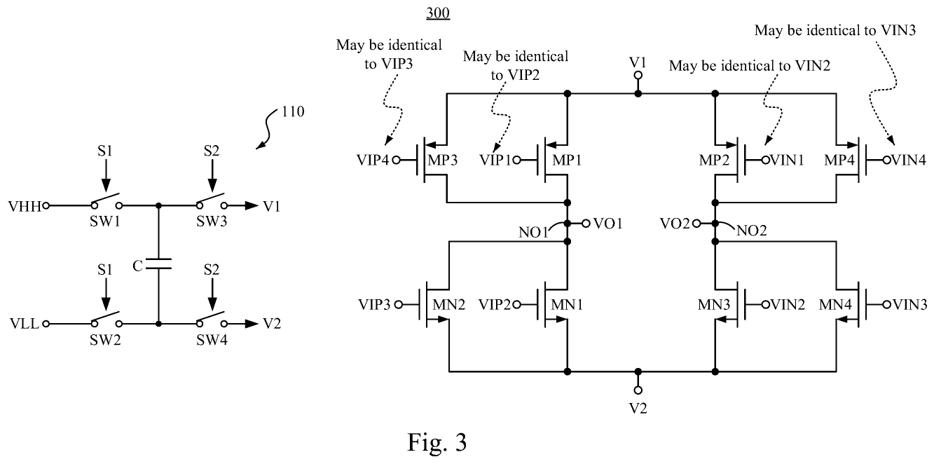

FIG. 3 illustrates a schematic diagram of a dynamic amplifier 300 according to some embodiments of the present disclosure. Compared with FIG. 2, in the dynamic amplifier 300, the input signal VIP4 may be identical to the input signal VIP3, the input signal VIP1 may be identical to the input signal VIP2, the input signal VIN4 may be identical to the input signal VIN3, and the input signal VIN1 may be identical to the input signal VIN2. In other words, in this embodiment, the transistor MP1 and the transistor MN1 are configured to amplify the input signal VIP2, and the transistor MP3 and the transistor MN2 are configured to amplify the input signal VIP3. Similarly, the transistor MP2 and the transistor MN3 are configured to amplify the input signal VIN2, and the transistor MP4 and the transistor MN4 are configured to amplify the input signal VIN3.

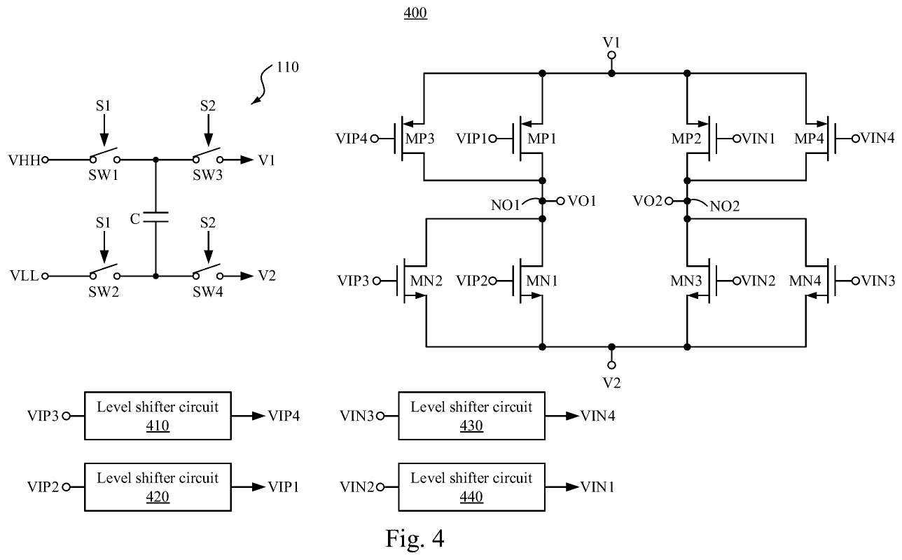

FIG. 4 illustrates a schematic diagram of a dynamic amplifier 400 according to some embodiments of the present disclosure. Compared with FIG. 2 or FIG. 3, in this embodiment, the input signal VIP4 is a signal generated based on the input signal VIP3, the input signal VIP1 is a signal generated based on the input signal VIP2, the input signal VIN4 is a signal generated based on the input signal VIN3, and the input signal VIN1 is a signal generated based on the input signal VIN2.

For example, the dynamic amplifier 400 further includes a level shifter circuit 410, a level shifter circuit 420, a level shifter circuit 430, and a level shifter circuit 440. The level shifter circuit 410 is configured to generate the input signal VIP4 according to the input signal VIP3, so that the input signal VIP4 and the input signal VIP3 have the same AC signal component and have different DC levels. The level shifter circuit 420 is configured to generate the input signal VIP1 according to the input signal VIP2, so that the input signal VIP2 and the input signal VIP1 have the same AC signal component and have different DC levels. The level shifter circuit 430 is configured to generate the input signal VIN4 according to the input signal VIN3, so that the input signal VIN4 and the input signal VIN3 have the same AC signal component and have different DC levels. The level shifter circuit 440 is configured to generate the input signal VIN1 according to the input signal VIN2, so that the input signal VIN2 and the input signal VIN1 have the same AC signal component and have different DC levels. In some embodiments, the input signal VIP4, the input signal VIP1, the input signal VIN1, and the input signal VIN4 may have the same DC level, but the present disclosure is not limited thereto.

In some embodiments, each of the level shifter circuit 410, the level shifter circuit 420, the level shifter circuit 430, and the level shifter circuit 440 may be implemented with a resistor and a capacitor. In some embodiments, each of the level shifter circuit 410, the level shifter circuit 420, the level shifter circuit 430, and the level shifter circuit 440 may be implemented with a transistor. The above implementations of the level shifter circuit 410, the level shifter circuit 420, the level shifter circuit 430, and the level shifter circuit 440 are given for illustrative purposes, and the present disclosure is not limited thereto.

It is understood that, in the above embodiments, the transistors may be directly coupled or may be coupled via other circuit components (for example, but not limited to, resistors, capacitors, diodes, or other transistors). Therefore, the contemplated scope of the present disclosure is not limited to the circuit arrangements shown in FIG. 1 to FIG. 4.

As described above, the dynamic amplifier provided in some embodiments of the present disclosure may simultaneously amplify multiple input signals and combine the amplified signals for output without using additional circuit(s), thereby avoiding unnecessary signal attenuation.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of present disclosure are all consequently viewed as being embraced by the scope of the present disclosure.

What is claimed is:

1. A dynamic amplifier, comprising:
a first transistor configured to amplify a first input signal;
a second transistor configured to amplify a second input signal;
a third transistor configured to amplify a third input signal, wherein the first transistor, the second transistor, and the third transistor are configured to collectively generate a first output signal at a first output node in response to the first input signal, the second input signal, and the third input signal;
a fourth transistor configured to amplify a fourth input signal;
a fifth transistor configured to amplify a fifth input signal;
a sixth transistor configured to amplify a sixth input signal, wherein the fourth transistor, the fifth transistor, and the sixth transistor are configured to collectively generate a second output signal at a second output node in response to the fourth input signal, the fifth input signal, and the sixth input signal; and
a power supply circuit configured to dynamically provide a plurality of power voltages to drive the first transistor, the second transistor, the third transistor, the fourth transistor, the fifth transistor, and the sixth transistor.

2. The dynamic amplifier of claim 1, wherein the second input signal and the fifth input signal are a first set of differential signals, and the third input signal and the sixth input signal are a second set of differential signals.

3. The dynamic amplifier of claim 1, wherein the first input signal is identical to the second input signal, and the fourth input signal is identical to the fifth input signal.

4. The dynamic amplifier of claim 1, wherein the first transistor and the second transistor are coupled in series through the first output node, and the third transistor is coupled in parallel to the second transistor.

5. The dynamic amplifier of claim 1, wherein the fourth transistor and the fifth transistor are coupled in series through the second output node, and the sixth transistor is coupled in parallel to the fifth transistor.

6. The dynamic amplifier of claim 1, further comprising:
a seventh transistor configured to amplify a seventh input signal, wherein the seventh transistor is coupled in parallel to the first transistor, and the seventh transistor, the first transistor, the second transistor, and the third transistor are configured to collectively generate the first output signal at the first output node; and
an eighth transistor configured to amplify an eighth input signal, wherein the eighth transistor is coupled in parallel to the fourth transistor, and the eighth transistor, the fourth transistor, the fifth transistor, and the sixth transistor are configured to collectively generate the second output signal at the second output node.

7. The dynamic amplifier of claim 6, wherein the seventh input signal is identical to the third input signal, and the eighth input signal is identical to the sixth input signal.

8. The dynamic amplifier of claim 7, wherein the first input signal and the fourth input signal are a first set of differential signals, and the third input signal and the sixth input signal are a second set of differential signals.

9. The dynamic amplifier of claim 6, wherein the first input signal and the fourth input signal are a first set of differential signals, the second input signal and the fifth input signal are a second set of differential signals, the third input signal and the sixth input signal are a third set of differential signals, and the seventh input signal and the eighth input signal are a fourth set of differential signals.

10. The dynamic amplifier of claim 6, wherein the first input signal is a signal generated based on the second input signal, the seventh input signal is a signal generated based on the third input signal, the fourth input signal is a signal generated based on the fifth input signal, and the eighth input signal is a signal generated based on the sixth input signal.

11. The dynamic amplifier of claim 6, wherein the seventh transistor and the third transistor are coupled in series through the first output node.

12. The dynamic amplifier of claim 6, wherein the eighth transistor and the sixth transistor are coupled in series through the second output node.

13. The dynamic amplifier of claim 6, wherein the first input signal and the second input signal have the same AC signal component and have different DC levels.

14. The dynamic amplifier of claim 6, wherein the seventh input signal and the third input signal have the same AC signal component and have different DC levels.

15. The dynamic amplifier of claim 6, wherein the fourth input signal and the fifth input signal have the same AC signal component and have different DC levels.

16. The dynamic amplifier of claim 6, wherein the eighth input signal and the sixth input signal have the same AC signal component and have different DC levels.

17. The dynamic amplifier of claim 1, wherein the power supply circuit comprises:
a first switch configured to be turned on according to a first switching signal to provide a first supply voltage;
a second switch configured to be turned on according to the first switching signal to provide a second supply voltage;
a capacitor configured to be charged via the first supply voltage and the second supply voltage;
a third switch coupled to a first terminal of the capacitor and configured to be turned on according to a second switching signal to provide a first power voltage in the plurality of power voltages; and
a fourth switch coupled to a second terminal of the capacitor and configured to be turned on according to the second switching signal to provide a second power voltage in the plurality of power voltages.
